(19) United States
(12) Patent Application Publication
(10) Pub. No.: US 2026/0349061 A1
(43) Pub. Date: Nov. 5, 2026

(54) SYSTEMS AND METHODS FOR COIL LOCALIZED ELIMINATION OF ALIASED NUCLEAR MAGNETIC RESONANCE SIGNAL

(71) Applicant: The Cleveland Clinic Foundation, Cleveland, OH (US)

(72) Inventors: Fadil Ali, Cleveland, OH (US); Xiaojuan Li, Cleveland, OH (US); Jeehun Kim, Cleveland, OH (US)

(21) Appl. No.: 19/666,760

(22) Filed: May 4, 2026

Related U.S. Application Data
(60) Provisional application No. 63/799,408, filed on May 3, 2025.

(51) Int. Cl. G01R 33/565; G01R 33/48; G01R 33/561; G01R 33/58

(52) U.S. Cl. CPC G01R 33/56545; G01R 33/4818; G01R 33/5611; G01R 33/583

(57) ABSTRACT

A method of magnetic resonance image reconstruction includes acquiring full calibration dataset across receive channels of a phased array coil, generating segmented calibration dataset including a target region of the full calibration dataset, and determining constraints that suppress signal originating from outside the target region based on the full calibration dataset and the segmented calibration dataset. The method also includes applying the constraints to k-space data acquired across the receive channels, and outputting channel images of the receive channels based on the k-space data with the applied constraints.

### CROSS REFERENCE TO RELATED APPLICATIONS

The application claims priority to and the benefit of U.S. Provisional Patent Application No. 63/799,408, filed on May 3, 2025, entitled “COIL LOCALIZED LOW-RANK ELIMINATION OF ALIASED NMR (CLEAN)”, the entirety of which is incorporated herein by reference.

### STATEMENT OF GOVERNMENT-SPONSORED RESEARCH

This invention was made with government support under AR077452 awarded by the National Institutes of Health. The government has certain rights in the invention.

### BACKGROUND

Magnetic resonance imaging (MRI) acquires data by exciting nuclear spins within a subject and spatially encoding the resulting signals using gradient magnetic fields. In many clinical applications, only a limited region within the excited volume is of diagnostic interest, such as the heart within a larger excited chest wall, or a single hip within the full bilateral pelvic anatomy. Reduced field-of-view (FOV) imaging techniques address this by prescribing spatial encoding only over a smaller target region of interest (ROI), thereby reducing acquisition time while maintaining spatial resolution within the ROI. However, because the transmit radiofrequency pulse typically excites spins throughout a full slice or volume, signal contributions from anatomy outside the prescribed ROI remain present in the acquired data and alias into the reconstructed image, producing wraparound artifacts that can obscure anatomical detail or mimic pathology. FIG. 1 illustrates a full FOV knee image showing the entirety of the excited volume acquired by a phased array receiver coil. FIG. 2 illustrates a reduced FOV image in which signal foldover from anatomy outside the prescribed field of view is superimposed onto the desired anatomy within the ROI.

Conventional approaches to mitigating aliasing artifacts generally require modifications to the MRI acquisition itself, such as spatially selective radiofrequency excitation pulses or pre-saturation bands. These pulse-sequence-based techniques impose constraints including non-uniform signal profiles, increased specific absorption rate, and the requirement for separate acquisitions for each desired ROI. Spatial beamforming-based reconstruction methods offer an alternative that leverages the spatial sensitivity differences among multiple receive coil channels to distinguish signal within the ROI from signal outside the ROI without modifying the acquisition pulse sequence. Region-optimized virtual coils (ROVir) is one such technique, which determines linear combination weights that optimize the ratio of signal power within the ROI to signal power outside the ROI.

However, because ROVir compresses the original receive channels into a smaller number of virtual coils, channel-specific information, including the separate magnitude and relative phase difference across voxels that are associated with each individual receive channel and the original channel sensitivity profiles, is lost and not independently recoverable from the virtual coil output. This loss of channel-specific phase information is especially problematic for phase-sensitive applications such as velocity-encoded blood flow imaging. Furthermore, ROVir attenuates the desired signal within the ROI itself, because the power-ratio optimization does not guarantee preservation of the full signal magnitude from each channel within the target region. Additionally, ROVir remains susceptible to residual contamination from signal outside the ROI, including residual aliasing artifacts, ghosting, ringing, and leakage that become particularly pronounced when applied to k-space data encoded for a small FOV. These concepts extend to simultaneous multi-slice (SMS) imaging, in which separating individual slice contributions from a composite signal presents a problem analogous to recovering a single ROI from a full-FOV acquisition, and existing beamforming approaches may exhibit cross-contamination between slices.

Accordingly, currently practiced methods for performing reduced-FOV imaging either require modification of the acquisition pulse sequence with associated constraints on scan flexibility, or rely on virtual coil beamforming techniques that sacrifice channel-specific magnitude and phase information and leave residual artifacts that may compromise diagnostic image quality.

### BRIEF SUMMARY

According to an aspect, a method of magnetic resonance image reconstruction includes acquiring a full calibration dataset across receive channels of a phased array coil, generating a segmented calibration dataset including a target region of the full calibration dataset, and determining constraints that suppress signal originating from outside the target region based on the full calibration dataset and the segmented calibration dataset. The method also includes applying the constraints to k-space data acquired across the receive channels, and outputting channel images of the receive channels based on the k-space data with the applied constraints.

According to another aspect, a method of magnetic resonance image reconstruction includes acquiring a calibration dataset across receive channels of a phased array coil, generating first k-space data of a full excited volume of the phased array coil and second k-space data of a target region within the full excited volume from the calibration dataset, and constructing a matrix from the first k-space data and the second k-space data. The method also includes determining constraints that suppress signal originating from outside the target region by identifying a null space of the matrix, and applying the constraints to additional k-space data acquired across the receive channels.

According to another aspect, a method of magnetic resonance image reconstruction includes applying constraints that suppress signal originating from outside a target region to k-space data acquired across receive channels of a phased array coil. The method also includes outputting channel images of the receive channels based on the k-space data with the applied constraints.

A method for suppressing out-of-region signal in magnetic resonance imaging (MRI) is disclosed, utilizing a low-rank, coil-localized reconstruction approach referred to herein as Coil Localized Elimination of Aliased NMR signal (CLEAN) to eliminate aliased signal contributions from outside a selected region of interest (ROI) while preserving individual receive-channel magnitude and phase information. The method includes acquiring and segmenting a full field-of-view (FOV) calibration dataset, assembling a structured calibration matrix from local multi-channel k-space neighborhoods, and determining a null space whose weight vectors cancel outside-region contributions. In embodiments, null-space constraints are imposed on acquired k-space data through low-rank matrix completion, enabling precise ROI isolation per receive channel without pulse-sequence modifications or additional hardware. The method provides improved signal preservation and reduced noise amplification, quantified as g-factor, relative to Region-Optimized Virtual Coils (ROVir). The method supports simultaneous multi-slice imaging with Controlled Aliasing in Parallel Imaging (CAIPI) shifting and minimal inter-slice contamination relative to Slice Generalized Autocalibrating Partially Parallel Acquisitions (Slice-GRAPPA). The method is applicable to balanced steady-state free precession (bSSFP) sequences for outflow artifact suppression and is compatible with existing clinical acquisition workflows.

### BRIEF DESCRIPTION OF THE SEVERAL VIEWS OF THE DRAWING

FIG. 1 is a composite of full FOV magnetic resonance images according to a known imaging method.

FIG. 2 is a composite of reduced FOV magnetic resonance images according to a known imaging method.

FIG. 3 is a flowchart illustrating a method for reconstructing magnetic resonance images, according to an embodiment.

FIG. 4 is a schematic diagram illustrating a multi-channel dependency of the method of FIG. 3.

FIG. 5 is a schematic diagram illustrating spatial decomposition of a full excited volume into a target ROI and a surrounding outside region, according to an embodiment.

FIG. 6 is a schematic diagram illustrating a calibration image and a masked calibration image in both spatial and k-space domains, according to an embodiment.

FIG. 7 is a schematic diagram illustrating construction of a calibration matrix from local multi-channel k-space neighborhoods extracted from the k-space data of FIG. 6.

FIG. 8 is a plot of a singular value spectrum of the calibration matrix of FIG. 7, illustrating determination of a null space.

FIG. 9 is a schematic diagram illustrating construction of an acquired-data matrix from multi-channel k-space data and iterative low-rank completion of the acquired-data matrix using the null space of FIG. 8.

FIG. 10 is a series of per-channel output images and a final composite image produced by the iterative low-rank completion of FIG. 9.

FIG. 11 is a set of phantom validation images comparing a CLEAN reconstruction to a ground-truth full FOV reference, according to an embodiment.

FIG. 12 is a comparison grid of in-vivo knee imaging results including full FOV, aliased, CLEAN, and ROVir reconstructions, according to an embodiment.

FIG. 13 is a schematic and image comparison of parallel imaging and spatial beamforming reconstruction approaches, according to an embodiment.

FIG. 14 is a set of bilateral hip imaging results illustrating selection of repositionable regions of interest from a single calibration dataset and corresponding CLEAN reconstruction images, according to an embodiment.

FIG. 15 is a set of fractional signal preservation maps and histograms comparing CLEAN and ROVir for bilateral hip imaging, according to an embodiment.

FIG. 16 is a set of simultaneous multi-slice imaging results including original slices, a CAIPI-shifted composite, CLEAN, ROVir, and Slice-GRAPPA reconstructions, and corresponding source-slice versus target-slice leakage matrices, according to an embodiment.

FIG. 17 is a set of cardiac imaging results including magnitude and phase images comparing full FOV, aliased, CLEAN, and virtual-coil beamforming reconstructions, according to an embodiment.

FIG. 18 is a set of imaging results including slice-encoded calibration partitions and comparisons of a 2D acquisition, a CLEAN reconstruction, a virtual-coil beamforming reconstruction, and a center slice of an eight-slice-encoded acquisition, according to an embodiment.

FIG. 19 is a set of signal-to-noise ratio maps and noise amplification factor maps comparing a CLEAN reconstruction and a virtual-coil beamforming reconstruction using a phantom, according to an embodiment.

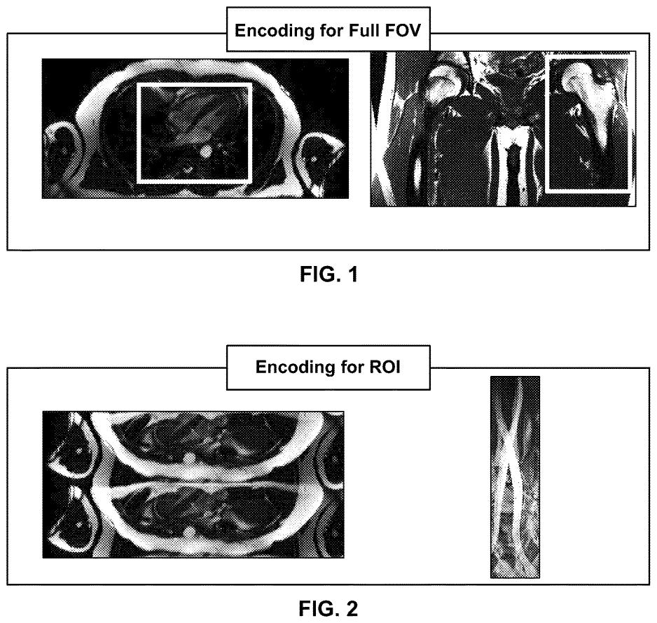

### DETAILED DESCRIPTION

Based on the foregoing, the present disclosure relates to a reduced FOV MRI reconstruction technique referred to herein as CLEAN, that suppresses signal originating outside a selected ROI while preserving separate receive-channel magnitude and phase information for each channel. Phased array MRI receivers collect data across multiple independent channels, and current reduced-FOV and simultaneous multi-slice (SMS) techniques either require pulse-sequence modifications or destroy per-channel information. The present technique relies on structured low-rank constraints derived from local k-space neighborhoods across all receive channels, rather than collapsing multiple channels into a virtual coil representation, and can reduce outside-ROI contamination while maintaining signal-to-noise ratio and phase fidelity. As a result, the methods and systems of the present disclosure may expand the range of data that can be collected in vivo by magnetic resonance (MR) systems, and can be incorporated into research or clinical imaging protocols on human or animal MRI scanners without requiring modifications to acquisition pulse sequences or scanner hardware.

Briefly, the methods and systems described herein use a calibration-driven reconstruction procedure that integrates a full-FOV calibration dataset with reduced-FOV acquisition data to cancel signal contributions from outside the selected ROI on a channel-by-channel basis. The technique relies on acquiring a full-FOV calibration dataset and selecting a target region of interest by applying a spatial mask to the calibration image. The masked and unmasked calibration images are each transformed to k-space and then split into two separate calibration k-space sets, one containing signal from all excited spins and one containing signal only from within the target region, both interpolated onto the reduced-FOV k-space spacing so that the target-region anatomy occupies the same voxel positions in both sets.

A structured calibration matrix is then constructed from local k-space neighborhoods extracted from both calibration k-space sets across all receive channels, and a null space of that matrix is determined via singular value decomposition. The null-space weight vectors define the vectorial cancellation of outside-ROI signal for any given channel. For a given reduced-FOV acquisition, the null-space constraints may then be imposed on the acquired k-space data to iteratively estimate separate reduced-FOV channel images, each preserving an original coil sensitivity profile and complex phase of the respective channel. In instances where the ROI is repositioned, the null-space operators may be recomputed for each ROI position, enabling multiple localized reconstructions from a common calibration dataset.

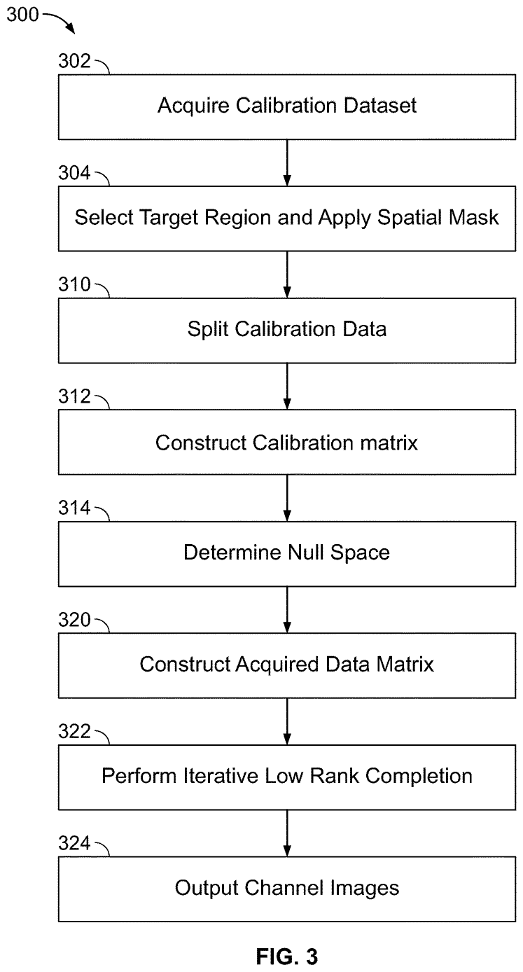

FIG. 3 depicts an example CLEAN reconstruction method 300 for suppressing out-of-region signal in magnetic resonance imaging is illustrated according to an exemplary embodiment described in connection with MRI data acquisition, processing, and reconstruction systems. For clarity, the method 300 is presented as a sequence of steps at blocks 302, 304, 310, 312, 314, 320, 322, and 324, but the steps may be performed in a different order, grouped into sub-processes, or implemented concurrently in other embodiments.

At block 302, the method 300 includes acquiring a calibration dataset covering a full excited volume across receive channels of a phased array coil. The calibration dataset acquired at block 302 encodes spatial information from both a target ROI and surrounding anatomy outside the target ROI, providing signal relationships that distinguish between signal originating within the target ROI and signal originating outside the target ROI in subsequent processing.

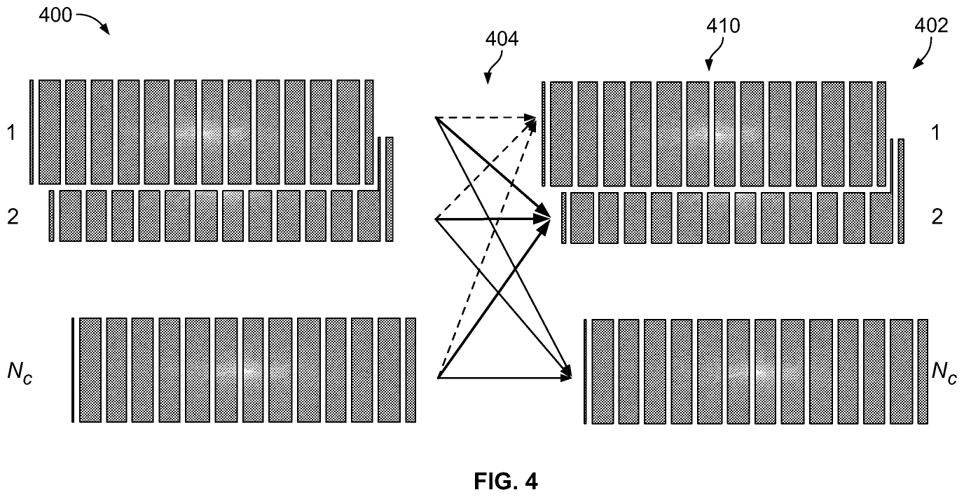

FIG. 4 is a schematic diagram illustrating a multi-channel dependency of the method 300. As shown in FIG. 4, reconstructing the ROI k-space for any individual receive channel relies on the acquired k-space data from all receive channels. The method 300 uses the k-space data of all channels jointly to vectorially cancel signal from the outside region Γ for each channel, producing separate reconstructed channel images 402 in which each channel retains the original coil sensitivity profile and complex phase of that coil. This multi-channel dependency distinguishes the method 300 from virtual-coil beamforming approaches that collapse the receive channels into a reduced set of virtual coils in which channel-specific magnitude and phase information is not independently recoverable.

Referring back to FIG. 3, in embodiments of the method 300, the calibration dataset acquired at block 302 may include data from a separate low-resolution, fast acquisition that adds minimal time to an overall imaging session. In additional or alternative embodiments, the calibration dataset may include embedded auto-calibration signal lines acquired as part of an accelerated parallel imaging acquisition. In this regard, a higher-resolution calibration dataset may improve reconstruction fidelity and outside-region suppression, while a lower-resolution calibration dataset may reduce overall scan time and facilitate integration into time-sensitive clinical protocols.

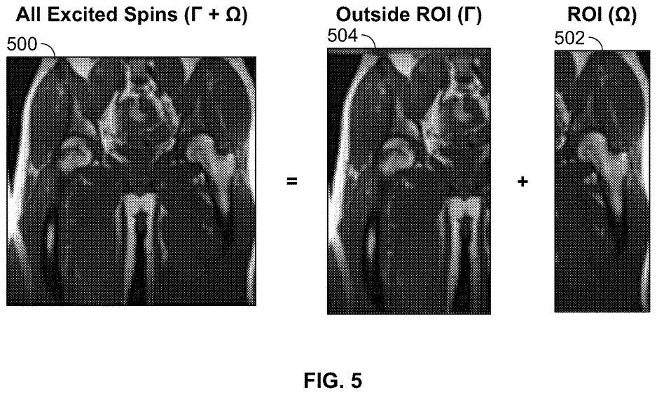

With reference to FIG. 5, the method 300 operates on a spatial decomposition of a full excited volume 500 into a target region of interest 502, referred to herein as Ω, and a surrounding outside region 504, referred to herein as Γ. As shown in FIG. 5, the full excited volume 500 includes signal from all spins within the imaging field, and the total signal at any k-space position may be represented as the sum of contributions from spins within the target region of interest 502 and spins within the outside region 504. The method 300 preserves the signal from the target region of interest 502 while vectorially canceling the signal from the outside region 504 across all receive channels.

The full excited volume 500 represents the full continuous spatial volume from which signal is excited during the acquisition and from which the target region is subsequently selected. The full excited volume need not span the entire spatial extent that the phased array coil is capable of receiving signal from, but encompasses at least the spatial extent that includes the target region and any surrounding anatomy that contributes signal to the acquired k-space data. The full calibration dataset acquired at block 302 encodes signal from the full excited volume 500, and the segmented calibration dataset is generated by selecting the target region from within the full excited volume 500.

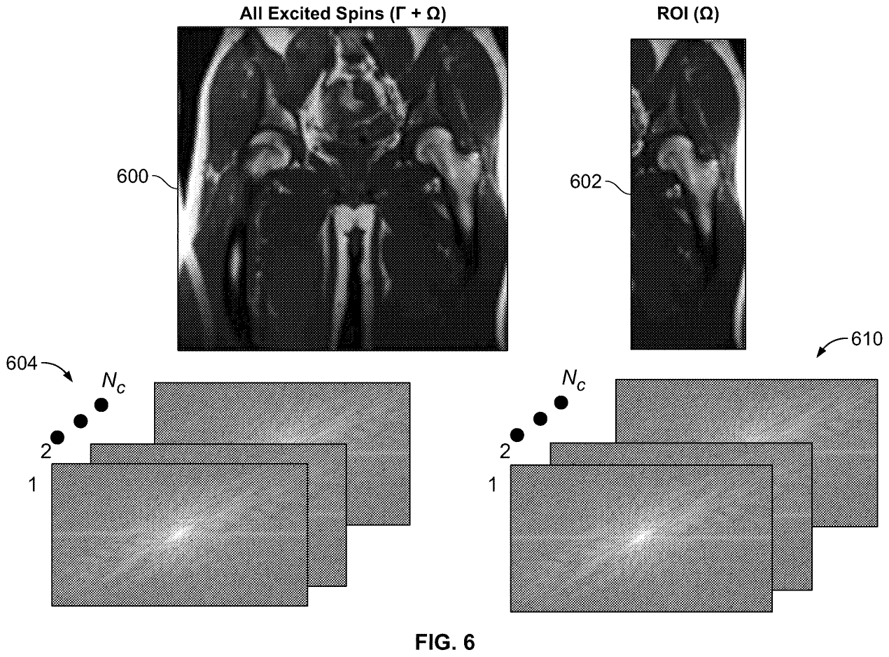

As shown in FIG. 3, block 304 of the method 300 includes selecting the target region Ω within the calibration dataset and applying a spatial mask. In this regard, FIG. 6 is a schematic diagram depicting a calibration image 600 encoding signal from the full excited volume 500, including both the target region Ω and the outside region Γ. The spatial mask applied at block 304 identifies the target region Ω within the calibration image 600 and sets signal outside the target region, referred to herein as the outside region Γ, to zero, retaining only signal originating from within the target region Ω. This produces a masked calibration image 602, which encodes spatial information from within the target region Ω alone. The calibration image 600 and the masked calibration image 602 are each Fourier transformed to obtain full-FOV k-space data 604 and ROI k-space data 610, respectively. As shown in FIG. 6, the full-FOV k-space data 604 and the ROI k-space data 610 are each represented as stacks of per-channel k-space datasets, one for each of the receive channels.

In embodiments, the spatial mask applied at block 304 may be a binary mask of arbitrary shape and is not limited to rectangular regions. For example and without limitation, the spatial mask may conform to anatomical boundaries, enabling targeted reconstruction of irregularly shaped structures such as a curved organ, a specific tissue compartment, or a single hip joint within a bilateral field of view. Also, the segmentation may be performed manually by a user, semi-automatically with user-guided boundary detection, or fully automatically using image processing or machine learning algorithms without departing from the scope of the present disclosure.

Referring back to FIG. 3, at block 310, the method 300 includes splitting the calibration data into two separate calibration k-space sets at reduced-FOV k-space spacing. After the spatial mask has been applied at block 304 to produce the masked calibration image 602, the method 300 generates two distinct calibration k-space datasets. The first calibration k-space set is an aliased calibration k-space set, which is generated by taking the full-FOV k-space data 604 and interpolating it onto a k-space grid defined by the reduced-FOV k-space spacing. The reduced-FOV k-space spacing corresponds to a k-space sample interval equal to the reciprocal of the field of view of the target region. This interpolation retroactively undersamples the full-FOV calibration to mimic the aliasing that occurs in an actual reduced-FOV acquisition, producing a low-resolution aliased calibration image in which signal from all excited spins, including spins within the target region and spins in the outside region, is present.

The second calibration k-space set is a target-only calibration k-space set, which is generated by taking the ROI k-space data 610, obtained from the masked calibration image 602, and interpolating it onto the same reduced-FOV k-space spacing. Because the masked calibration image 602 contains only signal from within the target region Ω, the target-only calibration k-space set encodes only the ROI contribution at the reduced-FOV k-space sample positions. In the target-only calibration k-space set, no aliasing is present because there is no signal from the outside region Γ to fold back into the target region.

Interpolating both calibration k-space sets onto the same reduced-FOV k-space spacing ensures that the anatomy within the target region Ω occupies the same voxel positions in both the aliased calibration k-space set and the target-only calibration k-space set. This spatial registration between the two calibration k-space sets is important for the subsequent construction of the calibration matrix, because the calibration matrix encodes the relationship between all-spin k-space neighborhoods and target-only k-space neighborhoods at corresponding spatial positions. If the two calibration k-space sets were sampled at different k-space spacings, the spatial correspondence between voxels in the target region would not be maintained, and the resulting null-space weight vectors would not accurately encode the cancellation of outside-ROI signal. By matching the k-space sample spacing of both calibration sets to the acquired reduced-FOV data, the calibration neighborhoods are sampled at positions commensurate with the reduced-FOV acquisition, enabling the null-space constraints derived from the calibration to be applied directly to the acquired data.

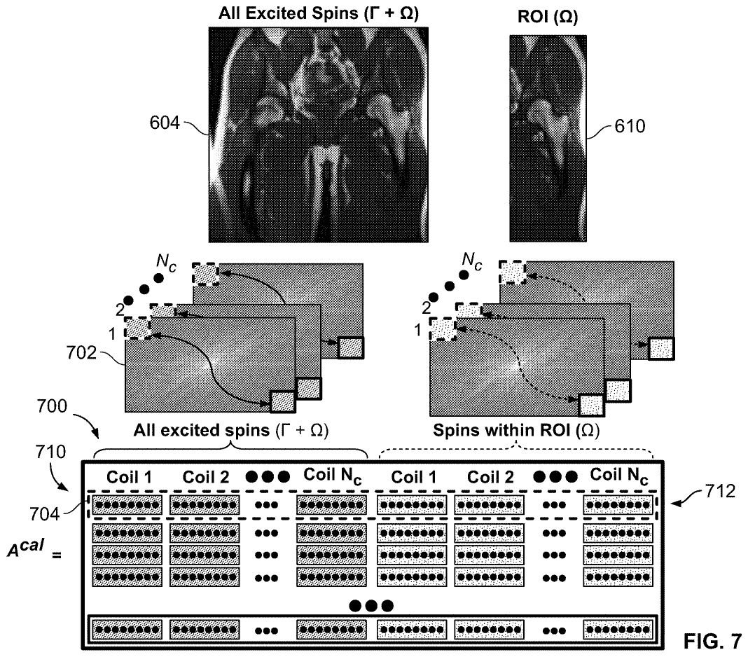

At block 312, the method 300 includes constructing a calibration matrix from local multi-channel k-space neighborhoods extracted from the aliased calibration k-space set and the target-only calibration k-space set. FIG. 7 is a schematic diagram illustrating construction of a calibration matrix 700 from the calibration k-space sets generated at block 310. The calibration k-space data depicted in FIG. 7 are represented on the reduced-FOV k-space grid, such that the target-region anatomy occupies corresponding voxel positions in both calibration sets.

As shown in FIG. 7, a kernel 702 defines a local neighborhood of k-space entries. The kernel 702 is slid across valid positions within a calibration k-space. At each kernel position, the neighborhood entries are extracted from each of the receive channels for both the full-FOV k-space data 604 and the ROI k-space data 610. The extracted entries are vectorized and concatenated into a single row 704 of the calibration matrix 700. A left half 710 of the row 704 contains the full-FOV k-space entries arranged in sequential channel order from a first channel through a last channel, and a right half 712 of the row 704 contains the ROI k-space entries arranged in the same channel order. Each row 704 of the calibration matrix 700 therefore contains entries for all channels and both the full-FOV and ROI k-space neighborhoods, and the number of rows equals the number of valid kernel positions within a calibration k-space grid. The calibration matrix 700 has a Block Hankel structure arising from the sliding-window extraction of overlapping k-space neighborhoods.

The two-half architecture of the calibration matrix 700 encodes complementary spatial relationships among multi-channel k-space entries. The left half 710 encodes linear relationships among k-space entries that exist in the full acquired data. These linear relationships arise as a structured low-rank property of smooth coil sensitivity functions, which create linear dependencies among multi-channel k-space entries at neighboring positions within the calibration matrix 700. The right half 712 encodes the same linear relationships as they exist within the ROI k-space data 610 alone. The left half 710 constitutes a first portion of the calibration matrix 700 and the right half 712 constitutes a second portion of the calibration matrix 700.

In this manner, the null space of the combined calibration matrix 700 identifies weight vectors that simultaneously satisfy both the full-FOV consistency and the ROI-only consistency constraints. Any such null-space weight vector of the calibration matrix 700, when applied to a multi-channel k-space neighborhood, necessarily produces zero net contribution from spins located in the outside region 504. In this regard, the calibration matrix 700 embeds both the full-spin and ROI-spin k-space neighborhoods in a single matrix, so that the null space inherently encodes the vectorial cancellation of signal from the outside region Γ.

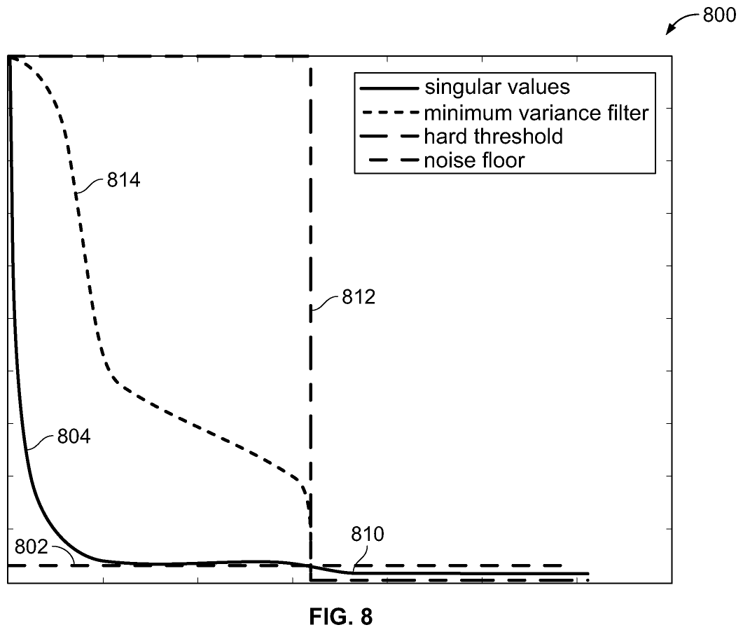

At block 314, the method 300 includes determining a null space of the calibration matrix 700. FIG. 8 is a plot of a singular value spectrum 800 of the calibration matrix 700, illustrating determination of the null space according to an embodiment. The method 300 computes a singular value decomposition (SVD) of the calibration matrix 700 to obtain a set of right singular vectors and corresponding singular values. The right singular vectors corresponding to singular values below a noise floor 802 span the null space of the calibration matrix 700.

As shown in FIG. 8, the singular value spectrum 800 illustrates a transition from significant singular values 804 to noise-level singular values 810 at or below the noise floor 802. Two thresholding approaches are disclosed for distinguishing the null space from a signal subspace. In a first approach, a hard threshold 812, in which all right singular vectors with singular values below a fixed cutoff are included in the null space, provides a sharp binary selection. In a second approach, a minimum variance filter 814 is applied in which right singular vectors are weighted by a continuous function that smoothly transitions from full inclusion to full exclusion based on proximity to the noise floor 802.

The null-space relationship identified at block 314 may be expressed as a summation equation. For any weight vector w in the null space of the calibration matrix 700, the following condition holds:

$${\sum }_{j = 1}^{{N}_{c}} {\sum }_{b = 1}^{{N}_{b}} {w}_{j}^{r ∈ Γ + Ω} ( b ) \cdot {d}_{j} ( {k}_{b} ) + {\sum }_{j = 1}^{{N}_{c}} {\sum }_{b = 1}^{{N}_{b}} {w}_{j}^{r ∈ Ω} ( b ) \cdot {d}_{j}^{r ∈ Ω} ( {k}_{b} ) = 0$$

where dⱼ(k_{b}) is a k-space neighborhood entry from channel j at position k_{b} for all excited spins,

$${d}_{j}^{r ∈ Ω} ( {k}_{b} )$$

is the corresponding entry for spins within the target region Ω, and the w terms are the corresponding weight coefficients for the full-spin and ROI-spin k-space entries, respectively. This equation states that for any null-space weight vector, the weighted sum of k-space entries across all channels and all neighborhood positions produces zero, vectorially canceling the signal contribution from the outside region Γ. The null-space weight vectors each define a set of inter-channel weights that cancel signal from outside the target region across the receive channels, and are determined from the null space of the calibration matrix 700.

At block 320, the method 300 includes constructing an acquired-data matrix from acquired multi-channel k-space data. At block 322, the method 300 includes performing iterative low-rank completion using the acquired-data matrix to estimate ROI k-space data for each of the receive channels.

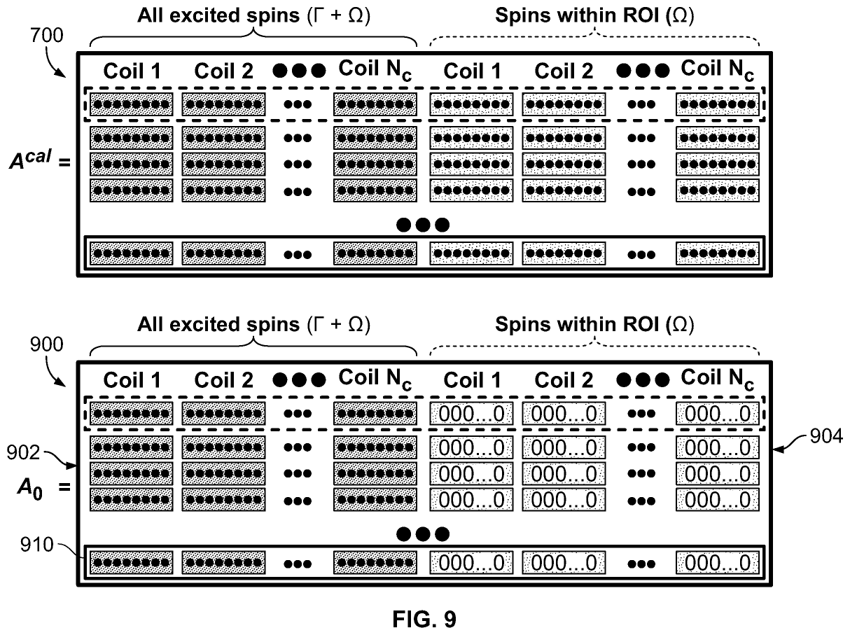

FIG. 9 is a schematic diagram illustrating construction of an acquired-data matrix 900 and iterative low-rank completion of the acquired-data matrix 900 using the null space determined at block 314, according to an embodiment. As shown in FIG. 9, the acquired-data matrix 900 is constructed from the acquired multi-channel k-space data, which may contain aliased signal contributions from outside the target region Ω. A left half 902 of the acquired-data matrix 900 contains the acquired k-space neighborhood entries, organized identically to the calibration matrix 700, with per-channel, per-neighborhood-position ordering. A right half 904 of the acquired-data matrix 900 is initialized to zeros, representing unknown reduced-FOV k-space entries that are to be estimated.

The null-space constraints determined at block 314 are imposed onto the acquired-data matrix 900 to iteratively estimate the unknown ROI k-space entries in the right half 904. In embodiments, this may be performed using Parallel Reconstruction Using Null Operations (PRUNO), which directly projects onto the null space, or Auto-Calibrated Low-Rank Modeling of Local K-Space Neighborhoods (AC-LORAKS), which solves a low-rank matrix completion problem. Other structured low-rank algorithms may be used without departing from the scope of the present disclosure, including iterative singular value thresholding, alternating direction method of multipliers (ADMM) solvers, or learned reconstruction networks. An iterative process progressively refines the unknown k-space entries in the right half 904 by repeated null-space projection, block Hankel consistency enforcement, and data consistency enforcement with the acquired entries in the left half 902 until convergence, which may be defined as a relative change in estimated k-space falling below a predefined threshold.

In this regard, the iterative process refines the unknown k-space entries in the right half 904. In each iteration of the iterative process, three operations are performed in sequence. First, the null-space weight vectors determined at block 314 are applied to enforce cancellation of outside-ROI signal contributions across all receive channels. Second, block Hankel consistency is enforced on the combined acquired-data matrix 900 to ensure that the estimated k-space entries satisfy the same structured low-rank relationships captured by the calibration matrix 700. Third, data consistency is enforced by replacing the entries in the left half 902 with the originally acquired k-space values, so that known data is not corrupted during the estimation of the unknown entries. The iterative process repeats these three operations until convergence.

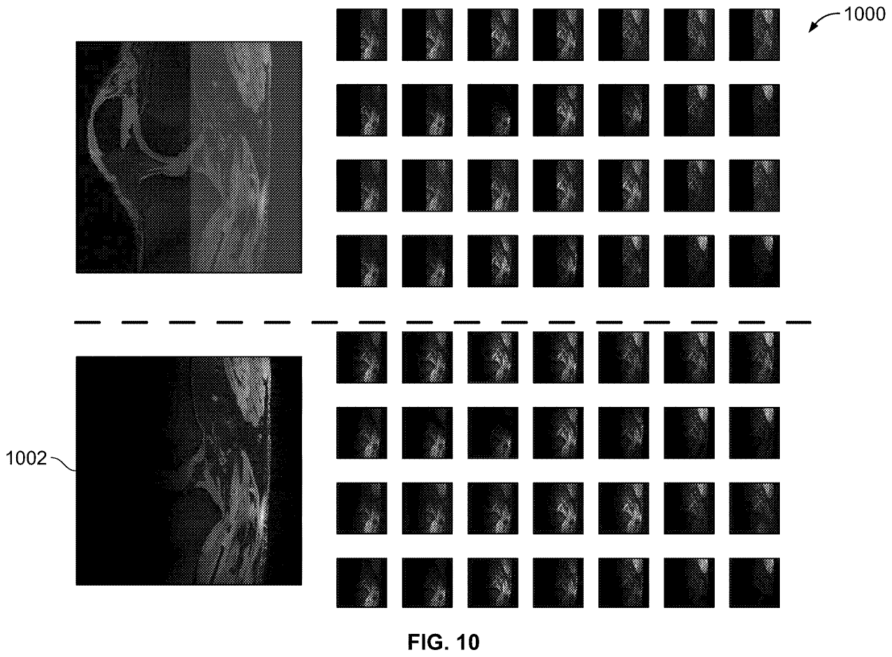

At block 324, the method 300 includes outputting, for each of the receive channels, a respective channel image containing signal from within the target region Ω. FIG. 10 is a series of channel images 1000 that are per-channel output images of the receive channels, and a final composite image 1002 produced by the iterative low-rank completion of FIG. 9, using the channel images 1000, according to an embodiment.

As shown in FIG. 10, the output of the reconstruction is a separate per-channel output image for each of the receive channels, each containing signal only from within the target region Ω and each retaining an original coil sensitivity profile and complex phase of the corresponding physical receive element. With this construction, the method 300 maintains channel-specific magnitude and phase information for every receive channel, which is a fundamental distinction from virtual-coil beamforming approaches that compress channels into a reduced representation in which per-channel information is not independently recoverable.

In embodiments, the channel images 1000 may optionally be combined into a single composite image, such as the composite image 1002 shown in FIG. 10. Any coil combination method may be used, including root-sum-of-squares (RSS), adaptive combination, or coil sensitivity-based combination such as SENSE-type combination, or other methods. Alternatively, the channel images 1000 may be used individually without combination for applications that require raw channel data, such as parallel imaging, phase-contrast velocity encoding, or susceptibility mapping.

The reconstruction performed by the method 300 is based on a signal model in which the k-space signal for channel l at position k is expressed as:

$${d}_{l} ( k ) = {d}_{l}^{r ∈ Ω} ( k ) + {d}_{l}^{r ∈ Γ} ( k ) + {n}_{l} ( k )$$

where

$${d}_{l}^{r ∈ Ω} ( k )$$

is the contribution from spins within the target region Ω,

$${d}_{l}^{r ∈ Γ} ( k )$$

is the contribution from spins in the outside region Γ, and nₗ(k) is noise. This decomposition holds for every k-space location and every channel independently, by the linearity of the Fourier transform.

The spatial smoothness of the coil sensitivity functions allows the ROI k-space for channel l at position k to be expressed as a weighted linear combination of all-channel neighborhood entries:

$${d}_{l}^{r ∈ Ω} ( k ) = {\sum }_{j = 1}^{{N}_{c}} {\sum }_{b = 1}^{{N}_{b}} {n}_{j}^{l} ( b ) \cdot {d}_{j} ( {k}_{b} )$$

This structured low-rank relationship arises because the smooth coil sensitivities create linear dependencies among multi-channel k-space entries at neighboring positions within the calibration matrix 700. The method 300 extends this property by incorporating the ROI segmentation at block 304 into the calibration, so that the resulting null space of the calibration matrix 700 specifically encodes the cancellation of outside-ROI signal rather than merely interpolating missing k-space entries.

The null-space constraint may also be expressed in compact form as:

[<ker(d(k)^{T},<ker(d^{r∈Ω}(k)^{T}]·w=0

which states that the concatenation of kernel representations for all-spin k-space and ROI-only k-space, multiplied by a weight vector w, equals zero. The calibration matrix 700 is constructed such that the rows of the calibration matrix 700 sample this relationship at every valid kernel position in the calibration dataset, and the null space of the calibration matrix 700 therefore provides a complete set of weight vectors that enforce vectorial cancellation of the outside-ROI contribution.

Referring back to FIG. 8, the two disclosed thresholding approaches may be further described. The hard threshold 812 selects all right singular vectors of the calibration matrix 700 whose corresponding singular values fall below a cutoff, providing a discrete null-space basis. The hard threshold 812 is computationally efficient and provides a clear delineation between the signal subspace and the null space. The minimum variance filter 814 applies a continuous weighting function across the singular vectors, smoothly transitioning from zero weight for large singular values to full weight for singular values well below the noise floor 802. The minimum variance filter 814 provides additional robustness to threshold selection and smoother null-space transitions. In embodiments, the noise floor 802 may be estimated from the data or specified by a user. Either approach may be selected based on the noise characteristics of the acquisition.

The neighborhood size of the kernel 702 affects the conditioning and effectiveness of the calibration matrix 700. Larger kernels capture more extensive spatial correlations among k-space entries, and may be effective up to a size that depends on the number of spatially unique channel sensitivity profiles along the direction of FOV reduction. Smaller sizes of the kernel 702 are also supported, enabling the method 300 to accommodate varying calibration dataset sizes and computational resources. In embodiments, the kernel 702 may be a rectangular block in k-space, for example five-by-five or seven-by-seven entries for two-dimensional imaging, or a three-dimensional block for volumetric imaging. The kernel dimensions may be selected based on the number of receive channels, the calibration dataset size, and the desired null-space dimensionality.

The calibration k-space should have enough valid kernel positions to adequately populate the calibration matrix 700. The number of valid positions depends on the calibration FOV, the resolution of the calibration dataset, and the dimensions of the kernel 702. In general, larger calibration datasets and smaller kernels produce more rows in the calibration matrix 700, improving the conditioning of the SVD. The calibration acquisition at block 302 should be fast and low-resolution to minimize additional scan time. In embodiments, the calibration scan may add less than one second to the overall acquisition time.

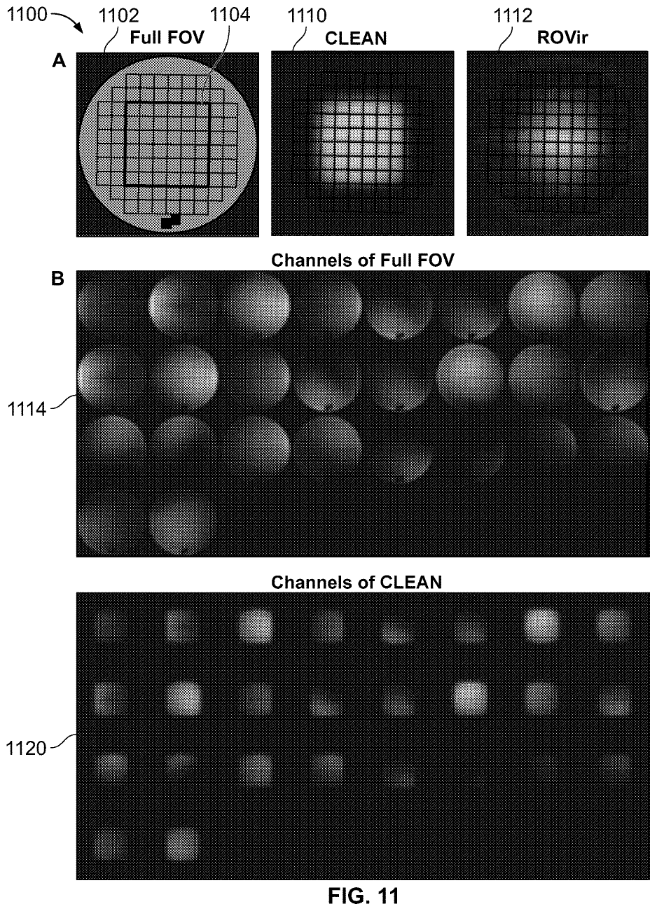

Referring to FIG. 11, an example phantom validation of the method 300 is illustrated according to an embodiment. A phantom having known geometry was imaged using a two-dimensional fast low-angle shot (FLASH) acquisition carried out on an American College of Radiology (ACR) phantom with a phased array coil having twenty-six receive channels. A square target ROI was selected within the image depicting the phantom.

FIG. 11 includes a full-FOV reference image 1100, a CLEAN reconstruction image 1102 produced by the method 300, and a virtual-coil beamforming reconstruction image 1104, produced using ROVir, for comparison. The CLEAN reconstruction image 1102 shows high fidelity to the full-FOV reference image 1100 within the target ROI, with effective suppression of outside-ROI signal.

FIG. 11 further includes individual channel images 1110, one for each of the receive channels, showing the coil sensitivity profile of each channel across the full field of view, and corresponding per-channel CLEAN images 1112, one for each of the receive channels, produced by the method 300. The individual channel images 1110 are arranged in a full-FOV channel image matrix 1114, and the per-channel CLEAN images 1112 are arranged in a CLEAN channel image matrix 1120. Each per-channel CLEAN image 1112 preserves the coil sensitivity profile of the corresponding channel image 1110 within the target ROI while suppressing signal from outside the target ROI. With this construction, the method 300 demonstrates that the reconstruction does not distort or blend the independent channel information, and the per-channel CLEAN images 1112 may be used directly as input to any downstream processing that requires raw per-channel data, including parallel imaging, phase-contrast velocity encoding, and susceptibility mapping.

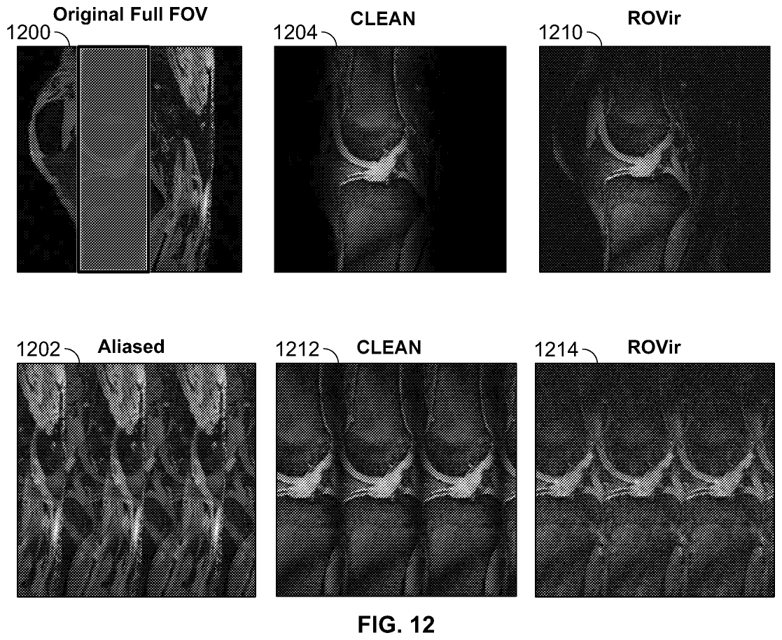

FIG. 12 depicts in-vivo knee imaging according to an embodiment. In this regard, a knee was imaged with a phased array coil having twenty-six receive channels using a Cartesian acquisition that encoded for half-FOV coverage, increasing spatial resolution within the target ROI, with signal from anatomy outside the prescribed FOV aliasing into the reduced encoding.

FIG. 12 includes a full-FOV reference image 1200, an aliased image 1202 exhibiting wraparound artifacts from the reduced encoding, a CLEAN reconstruction image 1204 produced by the method 300, and a virtual-coil beamforming reconstruction image 1210 produced using ROVir. The CLEAN reconstruction image 1204 is visually comparable to the full-FOV reference image 1200, with effective removal of the aliased signal. The virtual-coil beamforming reconstruction image 1210 shows residual signal contributions from outside the ROI, which are particularly noticeable as signal leakage that wraps over the anatomy of interest when applied to the reduced-FOV acquisition data.

An aliased image 1212 corresponds to the CLEAN reconstruction image 1204, and an aliased image 1214 corresponds to the virtual-coil beamforming reconstruction image 1210. The aliased images 1212, 1214 illustrate the respective residual aliased signal content associated with each reconstruction approach, further demonstrating the more complete suppression of outside-ROI signal achieved by the method 300 relative to virtual-coil beamforming.

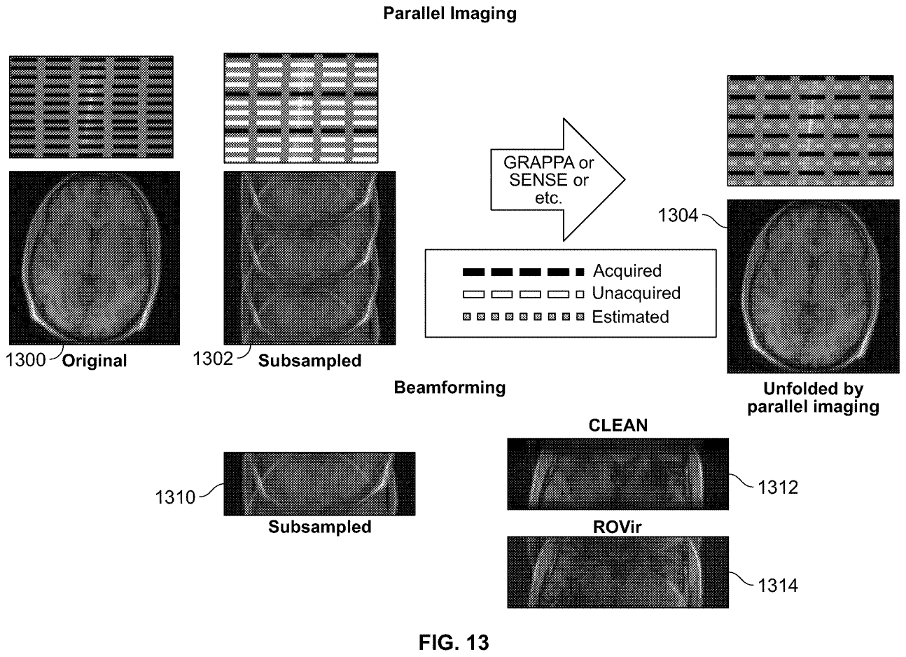

Referring to FIG. 13, a schematic and image comparison of parallel imaging and spatial beamforming reconstruction approaches is illustrated according to an embodiment. In parallel imaging, a fully sampled original image 1300 is related to a subsampled image 1302 by the sampling pattern. A parallel imaging algorithm such as GRAPPA or SENSE estimates unacquired k-space entries from the acquired data, using coil sensitivity information to unfold aliased signal and recover an unfolded image 1304 that approximates the original.

As shown in FIG. 13, the parallel imaging workflow operates by filling in missing k-space data and reconstructing a full-FOV image. In spatial beamforming, a subsampled image 1312 is processed by the method 300 or by a virtual-coil beamforming approach to suppress signal from outside the target region rather than unfolding it across the full FOV. The method 300 produces a CLEAN reconstruction image 1314, and the virtual-coil beamforming approach produces a ROVir reconstruction image 1320. The method 300 operates on the per-channel k-space data without altering the sampling pattern, and is therefore compatible with parallel imaging techniques. The method 300 can be applied in combination with parallel imaging to achieve both spatial signal suppression and acceleration from skipped k-space entries.

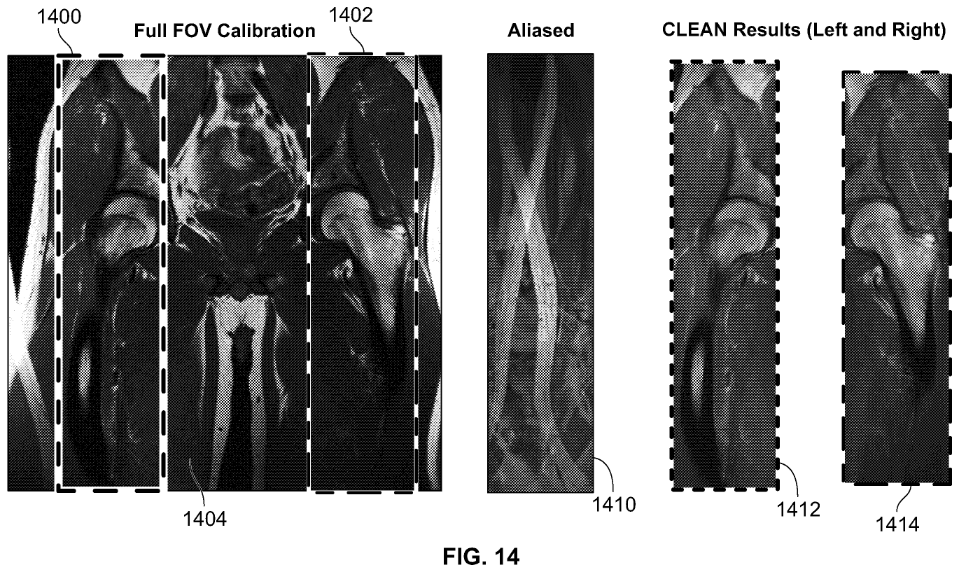

Referring to FIG. 14, bilateral hip imaging results are illustrated according to an embodiment, demonstrating a sliding-window ROI capability of the method 300. A single full-FOV calibration dataset was acquired covering both hips. Two separate ROIs were defined after the acquisition. A first ROI 1400 encompasses a left hip and a second ROI 1402 encompasses a right hip. FIG. 14 includes a calibration image 1404 showing the first ROI 1400 and the second ROI 1402 selected from the calibration image 1404, an aliased image 1410, and corresponding CLEAN reconstruction images 1412 and 1414 for the left hip and right hip, respectively.

The ROI segmentation and null-space determination are performed after the acquisition, enabling the ROI to be repositioned anywhere within the calibration FOV without re-acquiring data. Each ROI produced a separate set of channel images for each of the receive channels with the outside-ROI signal removed. As such, the described bilateral hip reconstruction demonstrates clinical utility of the sliding-window concept of the present disclosure, as a clinician can select and reconstruct any sub-region of interest from a single acquisition. In this manner, the method 300 supports workflows such as imaging both hips from a single scan without requiring separate acquisitions for each.

A three-metric evaluation framework is used to quantitatively compare the method 300 to virtual-coil beamforming. The first metric is fractional signal preservation, defined as the ratio of signal within the ROI after reconstruction to a ground-truth signal, measuring how much of the true signal is retained. The second metric is fractional leakage, defined as the ratio of residual outside-ROI signal after reconstruction to the original outside-ROI signal, measuring how effectively the unwanted signal is suppressed. The third metric is noise amplification, quantified as a g-factor, defined as the factor by which noise is amplified during reconstruction relative to a fully-sampled case. Lower g-factor values indicate less noise amplification and higher output signal-to-noise ratio, referred to herein as SNR.

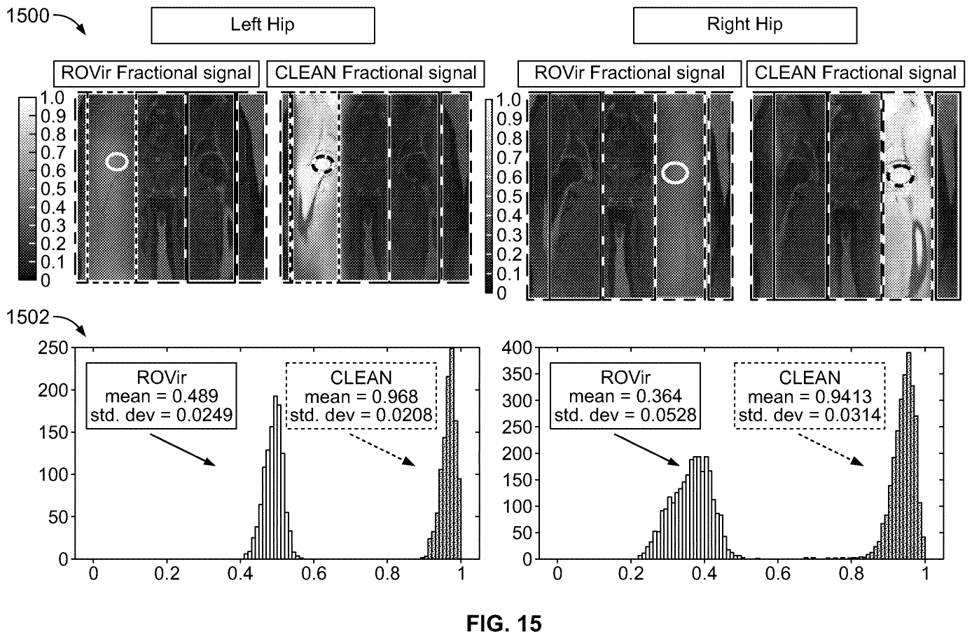

Referring to FIG. 15, fractional signal preservation results for bilateral hip imaging are illustrated according to an embodiment. FIG. 15 includes fractional signal preservation maps 1500 and corresponding histograms 1502 comparing CLEAN and virtual-coil beamforming, referred to above as ROVir, for the left hip and right hip of FIG. 14. For the left hip, CLEAN achieved a mean fractional signal preservation of 0.968 with a standard deviation of 0.0208, while ROVir achieved a mean of 0.489 with a standard deviation of 0.0249. For the right hip, CLEAN achieved a mean fractional signal preservation of 0.9413 with a standard deviation of 0.0320, while ROVir achieved a mean of 0.364 with a standard deviation of 0.0528.

As such, the method 300 preserves approximately 94-97% of signal within the ROI, while the virtual-coil beamforming approach preserves approximately 36-49%. The histograms 1502 show that the CLEAN signal preservation distribution is tightly concentrated near unity, whereas the ROVir distribution is broadly spread at substantially lower values. In addition to lower overall signal preservation, the virtual-coil beamforming approach exhibits non-uniform signal attenuation across the ROI. In the bilateral hip dataset, the virtual-coil beamforming approach achieved fractional signal uniformity across one hip ROI but not the other, indicating spatially varying signal loss. In contrast, the method 300 better preserves relative voxel values within the ROI, maintaining the original image contrast throughout the target region.

The method 300 also achieves substantially lower fractional leakage from outside the ROI compared to virtual-coil beamforming, indicating more effective cancellation of the unwanted signal contribution. Lower fractional leakage directly corresponds to fewer visible aliasing artifacts, ghosting, and ringing in the reconstructed images.

With respect to noise amplification, the method 300 shows significantly lower g-factor than virtual-coil beamforming across the ROI. In quantitative experiments, the noise amplification maps for virtual-coil beamforming required rescaling relative to those of the method 300 to be visible at the same display range, indicating a substantial difference in noise performance. The lower g-factor is a direct consequence of preserving per-channel data. The method 300 maintains the full multi-channel information, providing the reconstruction with more degrees of freedom available for noise mitigation. In contrast, channel compression in virtual-coil beamforming reduces the effective number of independent data streams, amplifying noise. The g-factor may be quantified as the ratio of the signal-to-noise ratio of the fully-sampled case to the product of the signal-to-noise ratio of the reconstruction and the square root of a FOV reduction factor. Lower g-factor translates directly to higher SNR in the clinical output images.

Signal-to-noise ratio was measured by acquiring multiple scans of an ACR phantom. Reconstruction operators determined from the first scan were applied to all subsequent scans, and SNR was computed for each voxel as the ratio of the mean signal to the standard deviation of the signal across all scans. The g-factor was then calculated from the SNR values accordingly. In this multi-scan evaluation, the method 300 preserved substantially more SNR than the virtual-coil beamforming approach, and the noise amplification maps for the virtual-coil beamforming approach required rescaling relative to those of the method 300 to be visible at the same display range.

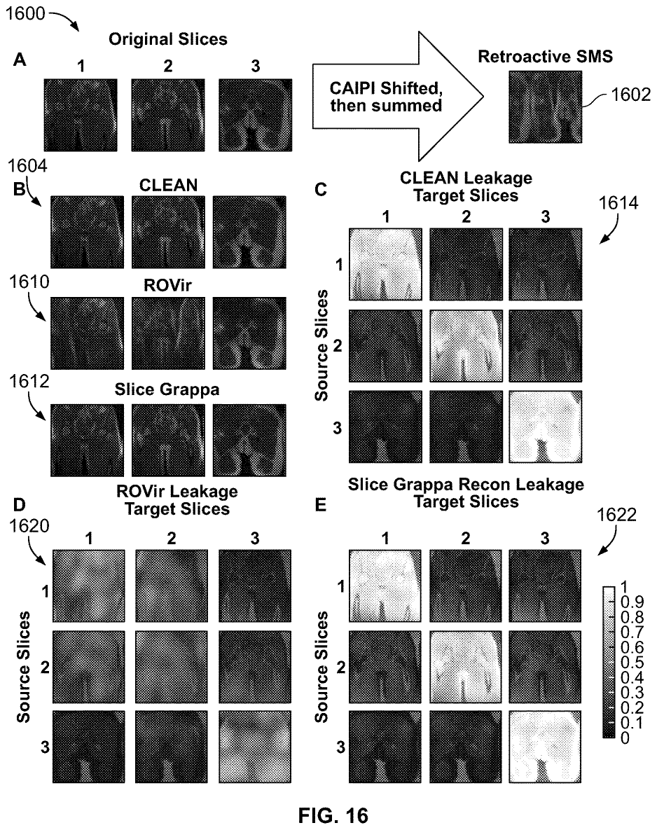

Referring to FIG. 16, SMS imaging results are illustrated according to an embodiment. In the SMS embodiment of the method 300, the general CLEAN framework is adapted to separate simultaneously acquired slices. Slices are acquired simultaneously with CAIPI phase cycling, creating a controlled inter-slice shift pattern. The phase cycling shifts aliasing patterns between slices of the simultaneous multi-slice data such that the overlapping signal contributions from different slices appear at different spatial offsets in each receive channel.

In the demonstrated embodiment, three coronal hip images were acquired separately. Each image, including the target-only slice, was shifted by a different third of the in-plane FOV using CAIPI phase cycling before the images were summed to produce a retrospective SMS dataset with controlled aliasing, generating collapsed multi-slice data. The CAIPI phase cycling was applied to each calibration slice, including the target-only calibration slice, before summation, so that the spatial offsets in the calibration data match the spatial offsets in the acquired collapsed multi-slice data. The collapsed multi-slice data is then reconstructed using the method 300, where each individual slice takes the role of the target region Ω in turn, and the contributions from the other simultaneously excited slices constitute the outside region Γ to be canceled.

FIG. 16 includes original slice images 1600, a CAIPI-shifted composite image 1602, CLEAN reconstructed slice images 1604, virtual-coil beamforming reconstructed slice images 1610, produced using ROVir, Slice Generalized Autocalibrating Partially Parallel Acquisitions (Slice-GRAPPA) reconstructed slice images 1612, and corresponding source-slice versus target-slice leakage matrices 1614, 1620, and 1622 for CLEAN, ROVir, and Slice-GRAPPA, respectively. The CLEAN leakage matrix 1614 and the Slice-GRAPPA leakage matrix 1622 both show bright diagonal entries near 1.0, indicating high signal preservation in the target slice, and dark off-diagonal entries near 0.0, indicating minimal cross-slice contamination. The ROVir leakage matrix 1620 shows notably brighter off-diagonal entries, indicating substantially more inter-slice leakage. With this construction, the method 300 achieves SMS slice separation quality comparable to a dedicated SMS reconstruction algorithm, such as Slice-GRAPPA, while using a general-purpose spatial beamforming framework.

With respect to noise amplification in the SMS context, the method 300 shows lower g-factor than virtual-coil beamforming for SMS reconstruction, consistent with the in-plane results described above. The SMS noise performance results demonstrate that the advantage of per-channel preservation extends to slice separation applications.

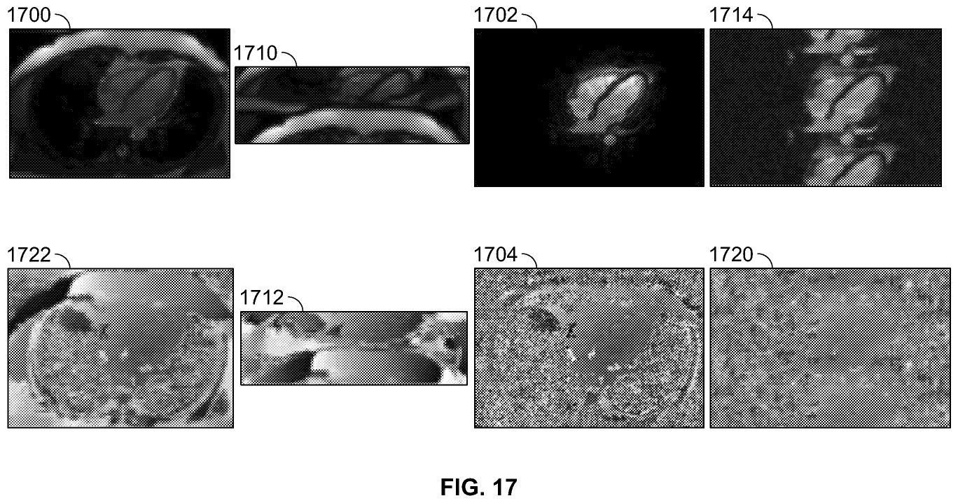

Referring to FIG. 17, a set of cardiac imaging results is illustrated according to an embodiment, demonstrating phase preservation by the method 300. The method 300 preserves per-channel complex phase as described above, enabling the output to be used for velocity-encoded cardiac imaging and flow quantification, both of which require phase information. The cardiac dataset was acquired in a horizontal long-axis orientation.

FIG. 17 includes a top row of magnitude images and a bottom row of corresponding phase images. The top row includes a full-FOV reference magnitude image 1700 with a cardiac ROI encompassing the heart and descending aorta, a CLEAN magnitude image 1702 demonstrating effective removal of aliased chest wall signal while preserving cardiac anatomy, an aliased magnitude image 1710 showing foldover from anatomy outside the cardiac ROI, and a ROVir magnitude image 1714 produced by the virtual-coil beamforming approach for comparison. The bottom row includes a CLEAN phase map 1704, an aliased phase map 1712, a ROVir phase map 1720, and a full-FOV reference phase map 1722, each corresponding to the respective magnitude image above. The CLEAN magnitude image 1702 shows high fidelity to the full-FOV reference magnitude image 1700 within the cardiac ROI, with effective suppression of aliased chest wall signal. In comparison, the ROVir magnitude image 1714 exhibits residual aliasing over low-signal regions, including aliased signal over the right ventricle from surrounding anatomy.

The CLEAN phase map 1704 demonstrates that the method 300 preserves the relative phase relationships needed for functional cardiac assessment, enabling downstream phase-sensitive analyses that would not be possible with virtual-coil beamforming approaches that compress channels into virtual coils. FIG. 17 further demonstrates that the method 300 can be integrated with parallel imaging reconstruction by recovering the per-channel ROI images from a dataset with skipped k-space entries, confirming that the CLEAN output is compatible with standard accelerated imaging workflows.

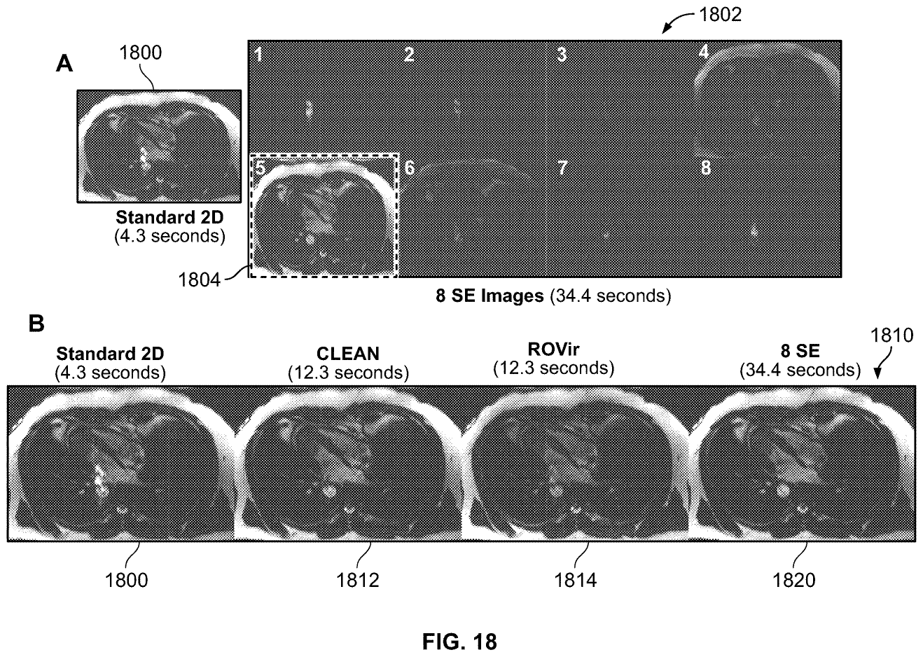

Referring to FIG. 18, a set of balanced steady-state free precession (bSSFP) imaging results is illustrated according to an embodiment, demonstrating outflow artifact suppression by the method 300. In bSSFP imaging, blood flowing through the imaging plane carries signal from outside the intended slice, producing outflow artifacts that corrupt the in-plane image. The method 300 treats this flow signal in the through-plane direction as signal from the outside region Γ and cancels it via the same null-space framework described above.

FIG. 18 includes a 2D cardiac image 1800 acquired in approximately 4.3 seconds, showing a transverse thoracic slice with the heart and surrounding thoracic anatomy. FIG. 18 further includes eight slice-encoded calibration partition images 1802 arranged in a grid and numbered 1 through 8. Each partition image represents a raw slice-encoded calibration acquisition, with partitions encoding different spatial positions along the slice direction. A highlighted border 1804 around partition image 5 indicates the target partition corresponding to the center slice containing the target ROI. The remaining partition images are predominantly dark with limited anatomical signal, reflecting the spatial encoding of signal across the multiple partitions. The eight slice-encoded calibration was acquired over approximately 34.4 seconds.

FIG. 18 further includes a set of comparison images 1810 arranged in a row. The comparison images 1810 include a 2D acquisition image obtained in approximately 4.3 seconds, a CLEAN reconstruction image 1812 produced by the method 300 in approximately 12.3 seconds, a virtual-coil beamforming reconstruction image 1814 obtained in approximately 12.3 seconds, and a center slice image 1820 extracted from the eight-slice-encoded acquisition obtained in approximately 34.4 seconds. The CLEAN reconstruction image 1812 and the 2D acquisition image appear visually comparable in depicting cardiac anatomy, with the heart chambers and surrounding thoracic structures preserved. The virtual-coil beamforming reconstruction image 1814 shows similar cardiac anatomy but is not identical in appearance to the CLEAN reconstruction image 1812. The center slice image 1820 provides comparable anatomical content to the CLEAN reconstruction image 1812 but required a substantially longer acquisition time. The comparison images 1810 demonstrate that the method 300 produces cardiac bSSFP images with reduced outflow artifacts at an acquisition time that is shorter than the full eight-partition slice-encoded acquisition and comparable to the virtual-coil beamforming approach.

The bSSFP results of FIG. 18 demonstrate that the ROI concept in the method 300 extends beyond in-plane spatial regions to signal selection in the slice direction. In this manner, the method 300 can separate signal contributions from any spatially distinct source, regardless of whether the aliasing arises from in-plane foldover, simultaneous multi-slice overlap, or flow in the through-plane direction.

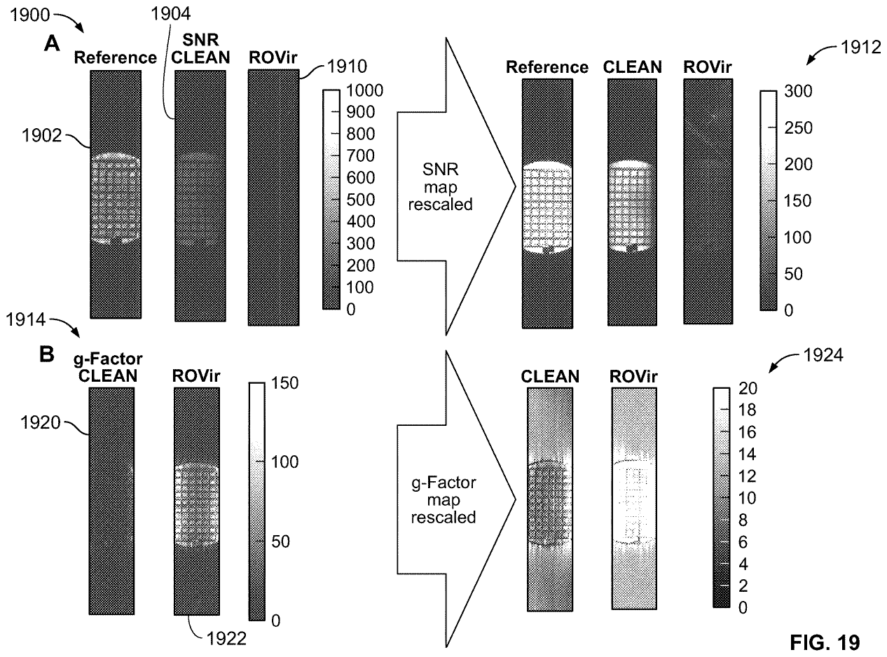

Referring to FIG. 19, signal-to-noise ratio (SNR) maps and noise amplification factor (g-factor) maps are illustrated according to an embodiment, comparing the method 300 with virtual-coil beamforming using a phantom imaging target. The phantom contains an internal grid lattice structure that enables visual assessment of spatial fidelity across reconstruction methods.

FIG. 19 includes a set of SNR maps 1900 for a fully-sampled reference reconstruction, a CLEAN reconstruction produced by the method 300, and a virtual-coil beamforming reconstruction produced using ROVir. A reference SNR map 1902 shows the highest signal level with the grid structure clearly visible. A CLEAN SNR map 1904 shows a slightly reduced signal level relative to the reference SNR map 1902, with the grid structure remaining visible, indicating substantial signal preservation. A ROVir SNR map 1910 appears significantly darker than both the reference SNR map 1902 and the CLEAN SNR map 1904, with the grid structure faint or barely visible, indicating substantially lower SNR. FIG. 19 further includes rescaled SNR maps 1912, produced by compressing the display range to enable visual comparison across all three methods. After rescaling, the ROVir SNR map 1910 becomes more visible but remains less uniform than the reference SNR map 1902 and the CLEAN SNR map 1904.

FIG. 19 includes a set of g-factor maps 1914 for the CLEAN reconstruction and the virtual-coil beamforming reconstruction. The g-factor maps 1914 represent the spatially varying noise amplification introduced by each reconstruction method, with higher g-factor values indicating greater noise amplification. A CLEAN g-factor map 1920 shows moderate and relatively uniform values across the phantom. A ROVir g-factor map 1922 shows higher overall values and greater spatial nonuniformity, with more pronounced artifacts at the lateral edges of the phantom. FIG. 19 further includes rescaled g-factor maps 1924, produced by compressing the display range. After rescaling, the ROVir g-factor map 1922 remains brighter and more nonuniform than the CLEAN g-factor map 1920. The g-factor comparison demonstrates that the method 300 introduces substantially less noise amplification than virtual-coil beamforming, consistent with the per-channel signal preservation achieved by the null-space cancellation framework of the method 300.

Referring back to the cardiac imaging results of FIG. 17, fractional signal preservation analysis was also performed, with the method 300 demonstrating similar advantages over virtual-coil beamforming as observed in the bilateral hip imaging results of FIG. 15. The ROI segmentation and reconstruction in the method 300 are performed post-acquisition, allowing the ROI to be repositioned anywhere within the calibration FOV without re-acquiring data. With this construction, the method 300 supports several clinical workflows. In an interactive targeting workflow, a clinician may select sub-regions of interest during image review. In an automated serial reconstruction workflow, multiple sub-regions may be reconstructed sequentially from a single acquisition. In a retrospective re-targeting workflow, the ROI may be adjusted after the scan session based on diagnostic findings. The only requirement is that the calibration dataset covers the full extent of possible ROI placements.

In embodiments, the spatial mask applied at block 304 is not limited to rectangular regions. The spatial mask may be any arbitrary two-dimensional or three-dimensional shape, conforming to anatomical boundaries. For example and without limitation, the spatial mask applied at block 304 may follow the curved boundary of a kidney, isolate a specific vertebral body, or delineate a tumor margin. With this construction, the method 300 enables targeted reconstruction that precisely matches the clinical ROI, minimizing the inclusion of extraneous tissue and maximizing computational efficiency.

The method 300 outputs separate channel images 1000 for each of the plurality of receive channels with preserved sensitivity profiles. As such, the output may be used as input to any parallel imaging reconstruction method, including GRAPPA, SENSE, or variants thereof. Any such parallel imaging reconstruction method may also include or be referred to as a parallel imaging reconstruction algorithm that operates on the channel images to produce a final reconstructed image.

For example, the method 300 may first remove aliasing from a specific anatomical target, and a subsequent GRAPPA or SENSE step may further accelerate the acquisition by filling in skipped k-space lines. In embodiments using SENSE-type reconstruction, which produces a coil-combined image, the combined image may be multiplied by individual channel sensitivity maps to recover per-channel estimates that are then provided as input to the method 300.

The preservation of per-channel complex phase by the method 300 enables a range of applications that require phase information. These applications of the channel images 1000 include phase-contrast velocity encoding for blood flow measurement, flow quantification in cardiac and vascular imaging, and Dixon fat-water separation, as demonstrated by the phase preservation results of FIG. 17. Additional phase-sensitive applications include susceptibility-weighted imaging (SWI), quantitative susceptibility mapping (QSM), temperature mapping for interventional MRI, and B0 field mapping. In each of these applications, the per-channel phase is essential for accurate quantification, and methods that compress channels into virtual coils cannot provide this information in a form that is independently recoverable for each physical receive element.

In the SMS embodiment, the general CLEAN framework of the method 300 is adapted to separate individual slice contributions from a composite multi-slice signal. In this regard, full excited spins include the superposition of all simultaneously excited slices, and for each target slice, the remaining slices constitute the outside region Γ. A slice-specific calibration matrix 700 is constructed for each target slice, with the left half containing multi-slice k-space neighborhoods and the right half containing single-slice k-space neighborhoods corresponding to the target slice. The null space of each slice-specific calibration matrix 700 encodes the cancellation of the non-target slices. The CAIPI phase cycling pattern, which creates predictable inter-slice shifts, ensures that the multi-channel k-space entries from different slices are sufficiently distinct to enable reliable null-space determination. The method 300 may be applied to simultaneously excited slices with any CAIPI shift factor. The number of slices that can be reliably separated depends on the channel sensitivity variability along the slice direction, with greater variability among receive channel sensitivity profiles enabling separation of a larger number of simultaneously excited slices.

While PRUNO and AC-LORAKS are disclosed as specific embodiments for imposing the null-space constraints at blocks 320 and 322, any structured low-rank matrix completion algorithm may be used without departing from the scope of the present disclosure, including but not limited to Simultaneous Autocalibrating and K-space Estimation (SAKE), Unfolding Coil Localized Errors Using a Structured Auto Calibration Matrix (UNCLE SAM), iterative singular value thresholding, alternating direction method of multipliers (ADMM) solvers, projected gradient descent, nuclear norm minimization, or learned and deep-learning-based reconstruction networks that incorporate the null-space constraint as a data consistency layer.

The method 300 is applicable to three-dimensional k-space by using three-dimensional kernel neighborhoods for the kernel 702. The target region Ω may be defined in any spatial dimension. For example and without limitation, the target region Ω may be defined as a two-dimensional in-plane region, as a one-dimensional selection in the slice direction, or as a three-dimensional volumetric region. The construction of the calibration matrix 700, the SVD, and the reconstruction steps remain structurally identical, with the kernel dimension and matrix size adjusted accordingly.

The method 300 is based on reconstruction of MR data and does not necessarily require any specific acquisition protocol, or changes thereto. However, the method 300 may still be combined with specialized acquisition techniques as a post-processing step. For example and without limitation, the method 300 may be applied to data acquired using SWEEP, a separate acquisition method for metal artifact reduction, to provide both artifact reduction and spatial beamforming in a combined workflow. In this regard, the method 300 treats the k-space data acquired using SWEEP as the acquired multi-channel k-space data at block 320, and the calibration dataset acquired at block 302 is acquired using the same acquisition technique. Because the method 300 operates on the acquired k-space data as a post-acquisition reconstruction operation, the method 300 does not require knowledge of or impose requirements on the acquisition technique used to generate the k-space data. The null-space constraints determined at block 314 suppress signal from the outside region Γ regardless of the acquisition technique, provided that the calibration dataset and the acquired k-space data are acquired under consistent spatial encoding conditions.

The method 300 is also compatible with non-Cartesian k-space trajectories, such as radial or spiral trajectories, provided that the calibration dataset is sampled on a compatible grid or regridded to Cartesian coordinates. In embodiments, the null-space determination at block 314 may be precomputed from the calibration dataset and stored, so that the iterative low-rank completion at blocks 320 and 322 can be performed in near real-time as acquired data becomes available. In this manner, the method 300 may support applications that require rapid feedback, including interventional MRI guidance and real-time cardiac imaging.

Any aspect of the above disclosure may be implemented by a processor of an MRI scanner, or by a processor of a separate computing device communicatively coupled to the scanner, on a remote cloud-based server, or on any combination thereof. The processor receives multi-channel k-space data from an MRI receiver and outputs reconstructed images to a display, a picture archiving and communication system (PACS), or another storage or transmission medium. It is further noted that any aspect may be executed locally, for example at the site of the MRI scanner, or remotely. For example, MR data acquisition may be performed locally to an MRI system at a hospital or similar clinical location, while other aspects of the present disclosure are performed at a remote central processing location and at a different time than the data acquisition.

In embodiments, the MRI system includes a main magnet generating a static magnetic field (B0), gradient coils for spatial encoding, and a radio-frequency (RF) transmit coil for spin excitation. A phased array receive coil including independent receive elements detects the MR signals, and analog-to-digital converters digitize the received signals. The MRI system further includes a processor, which may include one or more central processing units (CPUs), graphics processing units (GPUs), or specialized hardware accelerators. A memory stores k-space data, calibration parameters, null-space basis vectors, and reconstructed images, and an output interface transmits results to a display or storage medium.

The method 300 may be embodied as instructions stored on a non-transitory computer-readable medium, including but not limited to a hard disk, solid-state drive, optical disc, flash memory, or network-accessible storage. In such embodiments, the instructions, when executed by one or more processors, cause the processor to perform the steps of the method 300 as described herein.

While various features are presented above, it should be understood that the features may be used singly or in any combination thereof. Further, it should be understood that variations and modifications may occur to those skilled in the art to which the claimed examples pertain. The examples described herein are not limited to the specific embodiments illustrated and described, but rather, the scope of the present disclosure is defined by the appended claims and their equivalents.

What is claimed is:

1. A method of magnetic resonance image reconstruction comprising:
acquiring a full calibration dataset across receive channels of a phased array coil;
generating a segmented calibration dataset including a target region of the full calibration dataset;
determining constraints that suppress signal originating from outside the target region based on the full calibration dataset and the segmented calibration dataset;
applying the constraints to k-space data acquired across the receive channels; and
outputting channel images of the receive channels based on the k-space data with the applied constraints.

2. The method of claim 1, wherein determining the constraints comprises:
constructing a matrix from the full calibration dataset and the segmented calibration dataset; and
determining null-space weight vectors from a null space of the matrix that cancel signal from outside the target region across the receive channels, such that each of the channel images retains a coil sensitivity profile of a corresponding one of the receive channels.

3. The method of claim 2, wherein determining the null-space weight vectors comprises:
performing a singular value decomposition of the matrix; and
applying a hard threshold that selects right singular vectors of the matrix with singular values below a cutoff, or applying a minimum variance filter that weights right singular vectors of the matrix based on proximity to a noise floor.

4. The method of claim 1, wherein the full calibration dataset covers a full excited volume of the phased array coil, and the target region has a non-rectangular shape conforming to an anatomical boundary.

5. The method of claim 1, wherein the full calibration dataset comprises data from an acquisition separate from the k-space data, or embedded auto-calibration signal lines from a parallel imaging acquisition.

6. The method of claim 1, wherein the acquired k-space data comprises simultaneous multi-slice data, the target region includes one slice of the simultaneous multi-slice data, and all remaining slices of the simultaneous multi-slice data are outside the target region.

7. The method of claim 6, wherein acquiring the simultaneous multi-slice data comprises:
applying an inter-slice phase cycle that shifts aliasing patterns between slices of the simultaneous multi-slice data.

8. The method of claim 1, further comprising:
selecting the target region such that the target region includes a partition along a slice-encoding direction of the k-space data, and signal from remaining partitions of the k-space data along the slice-encoding direction originates from outside the target region.

9. A method of magnetic resonance image reconstruction comprising:
acquiring a calibration dataset across receive channels of a phased array coil;
generating first k-space data of a full excited volume of the phased array coil and second k-space data of a target region within the full excited volume from the calibration dataset;
constructing a matrix from the first k-space data and the second k-space data;
determining constraints that suppress signal originating from outside the target region by identifying a null space of the matrix; and
applying the constraints to additional k-space data acquired across the receive channels.

10. The method of claim 9, wherein the matrix includes a first portion containing first k-space neighborhood entries from the first k-space data, and includes a second portion containing second k-space neighborhood entries from the second k-space data.

11. The method of claim 10, further comprising:
extracting the first k-space neighborhood entries and the second k-space neighborhood entries by sliding a kernel across positions within the first k-space data and the second k-space data.

12. The method of claim 9, further comprising:
interpolating the first k-space data and the second k-space data onto a k-space grid defined by the target region before constructing the matrix.

13. The method of claim 9, wherein identifying the null space comprises:
performing a singular value decomposition of the matrix and selecting right singular vectors of the matrix based on singular values from the singular value decomposition.

14. The method of claim 9, wherein the target region is a first target region, the matrix is a first matrix, the constraints are first constraints, and the method further comprises:
selecting a second target region within the full excited volume;
generating third k-space data of the second target region from the calibration dataset;
constructing a second matrix from the first k-space data and the third k-space data;
determining second constraints that suppress signal originating from outside the second target region by identifying a null space of the second matrix; and
applying the second constraints to the additional k-space data acquired across the receive channels.

15. A method of magnetic resonance image reconstruction comprising:
applying constraints that suppress signal originating from outside a target region to k-space data acquired across receive channels of a phased array coil; and
outputting channel images of the receive channels based on the k-space data with the applied constraints.

16. The method of claim 15, wherein applying the constraints comprises:
constructing a matrix from the k-space data and estimating k-space data of the receive channels corresponding to the target region by repeated projection of the matrix onto a null space defined by the constraints, such that the estimated k-space data converges toward or remains consistent with the k-space data.

17. The method of claim 15, wherein outputting the channel images comprises:
retaining a coil sensitivity profile and complex phase of a corresponding one of the receive channels in each of the channel images by reconstructing each of the receive channels by estimating separate k-space data for each of the receive channels.

18. The method of claim 17, further comprising:
performing at least one of phase-contrast velocity encoding, flow quantification, Dixon fat-water separation, susceptibility-weighted imaging, quantitative susceptibility mapping, temperature mapping, or B0 field mapping on the channel images using the complex phase.

19. The method of claim 15, further comprising:
combining the channel images into a composite image using at least one of root-sum-of-squares combination, adaptive combination, or coil sensitivity-based combination, or inputting the channel images to a parallel imaging reconstruction algorithm.

20. The method of claim 15, further comprising computing and storing the constraints from calibration dataset acquired across the receive channels before acquiring the k-space data.
